(19) United States
(12) Patent Application Publication
(10) Pub. No.: US 2026/0160802 A1
(43) Pub. Date: Jun. 11, 2026

(54) APPLYING PACKET-BASED TESTS THROUGH HIGH-SPEED INTERFACES USING AUTOMATIC TEST EQUIPMENT SYSTEMS AND APPLICATIONS

(71) Applicant: NVIDIA Corporation, Santa Clara, CA (US)

(72) Inventors: Mahmut Yilmaz, Los Altos Hills, CA (US); Shantanu Sarangi, Saratoga, CA (US); Kaushik Narayanun, Los Gatos, CA (US); Vishal Agarwal, Santa Clara, CA (US); Francisco da Silva, Morgan Hill, CA (US); Joefril Rubin Sarmiento, Livermore, CA (US)

(21) Appl. No.: 18/973,772

(22) Filed: Dec. 9, 2024

(51) Int. Cl. G01R 31/28

(52) U.S. Cl. CPC G01R 31/2834

(57) ABSTRACT

In various examples, Automatic Test Equipment (ATE) tests may be applied to electronic components, or devices under test (DUTs), using high-speed functional interfaces. For instance, a DUT and an ATE host device may be configured to perform one or more handshake mechanisms to optimize ATE test flows. The handshakes may be used to pause and/or resume a test interface executing on the DUT. In some examples, the ATE host device and the DUT may use one or more common data storage locations for performing the handshakes, such as system memory of the ATE host device, addressable register space of the DUT, a combination thereof, or any other shareable memory space. Additionally, the test interface of the DUT may be configured to convert packetized test data received using the high-speed functional interface to a raw data format consistent with traditional ATE test inputs received using I/O pins of the DUT.

### BACKGROUND

Electronic components—such as integrated circuits, semiconductor devices, or system-on-chips (SoCs)—are generally tested using automatic test equipment (ATE). However, ATE testing can often be expensive, and ATE costs may be proportional to the number of channels, speed, and/or vector memory requirements per channel. Thus, as chip sizes grow, demand for memory per input/output (I/O) may increase for low defective-parts-per-million (DPPM) testing. In most cases, additional I/Os may not be available for testing and/or the speed of test paths through the existing I/Os may not be improved. Additionally, with 2.5D and 3D chips becoming more mainstream, the number of available I/Os to be used for testing have further decreased. While compression schemes and other techniques have aimed to achieve lower test-data volumes, they come at the cost of poor diagnosability or vendor-specific design customizations, thereby increasing the chip costs. This causes test costs to increase drastically.

### SUMMARY

Embodiments of the present disclosure relate to applying packet-based tests through high-speed interfaces using automatic test equipment (ATE) systems and applications. Systems and methods are disclosed that may apply packetized versions of ATE tests to electronic components, or devices under test (DUTs), using high-speed functional interfaces (e.g., PCIe, USB, etc.). For instance, a DUT and an ATE host device may be configured to perform one or more handshake mechanisms to optimize ATE test flows. The handshakes may be used to pause and/or resume a test interface executing on the DUT such that the ATE host device and/or ATE client device may evaluate test results and perform test decision tree processing. In some examples, the ATE host device and the DUT may use one or more common data storage locations for performing the handshakes, such as a system memory of the ATE host device, addressable register space of the DUT, a combination thereof, or any other shareable memory space. Additionally, the test interface of the DUT may be configured to convert the packetized test data received using the high-speed functional interface to a raw data format consistent with traditional ATE test inputs received using I/O pins of the DUT. For instance, the test interface may extract test data (e.g., representing raw input data) from the packets and use information contained in packet headers to determine a test network (e.g., System for Core Analysis and Nondestructive Testing (SCAN), Joint Test Action Group (JTAG), etc.) of the DUT to apply the test data to.

In contrast to conventional systems, the systems of the present disclosure, in some embodiments, are able to leverage high-speed functional interfaces (e.g., high-speed I/O (HSIO) interfaces, PCIe, USB, etc.) of electronic components to apply ATE tests. As described in more detail herein, by sending packet-based versions of ATE tests to electronic components over functional interfaces, the systems of the present disclosure may enable faster debugging and testing without requiring additional I/Os (e.g., I/O pins) and/or hardware modifications. Additionally, in contrast to conventional systems, the systems of the present disclosure, in some embodiments, are able to reliably allow the use of packetized test data-based methods (e.g., Nvidia's MATHS) on ATE platforms by resolving handshake mechanisms for packetized test data on ATE and enabling debug and failure analysis features.

### BRIEF DESCRIPTION OF THE DRAWINGS

The present systems and methods for applying packet-based tests through high-speed interfaces using ATE systems and applications are described in detail below with reference to the attached drawing figures, wherein:

FIG. 1 illustrates an example of a system that may be used to apply packet-based ATE tests through high-speed interfaces, in accordance with some embodiments of the present disclosure;

FIG. 2 illustrates an example of a relay that may be used to select whether to apply packetized data or ATE channel data, in accordance with some embodiments of the present disclosure;

FIGS. 3A-3C illustrate a data flow diagram of an example handshake process that may be performed to apply packet-based ATE tests to a DUT, in accordance with some embodiments of the present disclosure;

FIG. 4 illustrates an example data flow of packetized test data within a DUT, in accordance with some embodiments of the present disclosure;

FIG. 5 is a flow diagram illustrating an example of a method for using handshakes to optimize ATE test flows and pause/resume a test interface executing on a DUT, in accordance with some embodiments of the present disclosure;

FIG. 6 is a flow diagram illustrating an example of a method for using packetized test data to apply an ATE test to a portion of a DUT, in accordance with some embodiments of the present disclosure;

FIG. 7 is a block diagram of an example computing device suitable for use in implementing some embodiments of the present disclosure; and

FIG. 8 is a block diagram of an example data center suitable for use in implementing some embodiments of the present disclosure.

### DETAILED DESCRIPTION

Systems and methods are disclosed related to applying packet-based tests through high-speed interfaces using ATE systems and applications. For instance, a system(s) may include a host device (e.g., an ATE host device) and a client device (e.g., an ATE client device), and the system(s) may be configured to send/apply packetized test data (e.g., packets containing ATE tests) to an electronic component (e.g., a semiconductor device, a system on a chip (SoC), an integrated circuit, etc.), which may be referred to herein as a device under test (DUT), using a functional interface associated with the electronic component, such as a USB interface, a PCIe interface, or any other HSIO interface. In some examples, the client device may determine the specific test that is to be executed and send an indication of the test to the host device. The host device may cause a test image of the test to be sent as packetized data to the DUT via the functional interface, and logic on the DUT may convert the packetized data to raw data representative of raw test inputs applied directly to input pins of the DUT by the client device. The logic on the DUT may further packetize results of the test and send the packetized results back to the host device via the functional interface. The host device may forward the results of the test to the client device, and the client device may determine whether the DUT passed the test, as well as next actions to be taken (e.g., discard the DUT, apply additional tests, etc.).

In some examples, to be able to run traditional ATE tests, defect-free test logic may be necessary. For instance, if the test-logic itself is defective, a DUT may immediately fail ATE testing and get discarded. In some instances, such as when packetized test data-based architectures for ATE testing are used, the test-logic may include some of the functional blocks as well. More specifically, if PCIe and/or other functional interfaces are used as a data interface, the physical layer (UPHY) and a portion of the PCIe logic may be used for packetized testing and they may need to be defect-free. In traditional ATE testing, if there are defects in the test-logic, test responses may fail. In the case of packet-based testing use cases, if there are defects in the PCIe logic or UPHY, the defects may cause hang issues on the host PC connected to ATE head. As such, the system(s) of the present disclosure may provide a backbone test, that may be run before packet-based testing may start. The backbone test may use, in some instances, traditional ATE setups with minimal numbers of pins. In some examples, UPHY/PCIe pins may also be used for this purpose. The packet-based test control logic and/or supporting PCIe logic may be wrapped into a circuit block, which may be isolated from other logic. The backbone logic may be completely tested before starting packet-based testing to minimize or eliminate the risk of stall conditions that can increase the overall test-time.

In various examples, ATE testing may not be composed of a single stream of test-vectors. Instead, ATE testing may include various test types and corresponding test-vectors. As such, ATE testing may be generally described as a decision tree, where results of a previous test(s) is used for deciding which test to run next. In some examples, the systems of the present disclosure may support a handshake mechanism for optimal test flow and to eliminate any risk of race conditions. The handshake mechanism may, in some instances, be referred to herein as a “pause/resume handshake.” As described in further detail herein, this pause/resume handshake may be used for various purposes, in addition to basic ATE decision tree processing.

In some examples, the pause/resume handshake may be performed using a common data storage location that both the test software (e.g., MATHS software, etc.) running on the host device and the test hardware (e.g., MATHS hardware, etc.) on the DUT can read and write to. The flow of test and behavior of the test hardware can be controlled by the test software using this common handshake location. For example, if a PCIe interface is used to fetch data from the host device's system memory, the handshake location may be a reserved memory location on the system memory, or it can be a region of the BAR addressable register space on the DUT, or it can be a combination of both (e.g., to optimize handshake latency). While these are just a couple of examples, it is to be understood that other options may be used if data fetching is done by other means (e.g., if UFS or NVMe is used as the data storage, the handshake location can be a reserved location on the flash drive itself).

As an example of how the system(s) of the present disclosure may use the pause/resume handshake, the host device—or test software executing on the host device—may store a test image for an ATE test that is to be applied to the DUT in the shared memory that is accessible to the DUT via the functional interface. In some instances, the host device may indicate in the test image that the test hardware/logic on the DUT should go into “pause” mode after completing the executing of the corresponding test image. Additionally, in some examples, the host device may, within the same test image, also indicate the memory location that shall be used for the pause/resume handshake, along with a signature that should be written to the specified memory location. In other words, the host device may modify the test image so that the DUT—or the test interface/logic on the DUT—knows to enter pause mode after executing the test image, as well as to inform the DUT of the memory location and signature the DUT is to use for performing the handshake. In at least one example, handshake signatures may be selected to have error correcting codes. In doing so, the system(s) of the present disclosure may guarantee more reliable operation, since soft-errors and single-bit upsets may not cause incorrect behavior.

In some examples, the host device may perform an initial handshake to cause the test logic on the DUT to “resume.” As such, the DUT may use the functional interface to obtain the test image stored in the memory, which includes the handshake/pause instructions. In some examples, this initial handshake may be performed by the host device writing to an addressable register associated with the functional interface. For instance, the host device may write “1111” to the register which may cause the DUT to resume testing. Additionally, or alternatively, the handshake may be implicit. As an example, the host device may have stored the test image to a placeholder location in memory specified, in a previous test image, as the next location in memory where the next test image may be stored. As such, the DUT may monitor the placeholder location and once the test image is stored there, the DUT may obtain the test data and the test logic may resume. In even further examples, if the test image is a first test image of a series of tests to be applied to the DUT, the test logic on the DUT may be in a “ready” state and the handshake to resume the test logic may not be necessary.

In some examples, once the test logic on the DUT completes execution of the test image, the DUT may write the specified signature to the specified memory location from the test image, thereby indicating that the image execution is complete and the test logic/interface has entered the pause state waiting for further instructions from the host device. That is, since the current test image requested the pause, the test interface of the DUT may activate/enter the pause state before starting to read the next test image, and the test interface may enter the pause state after a test results packet(s) is written back to the system memory. By writing the specified signature to the specified memory locations, the DUT may perform the handshake and the host device may know that the results are stored at the memory location (or another specified memory location).

In some examples, based at least on the handshake, the host device may obtain the results for the test from the memory. In some instances, the host device may send the results to the client device managing the ATE test. The client device may evaluate the results and make a test decision, which may be provided back to the host device. For instance, the client device may determine the DUT passed the test and send an indication of the next test to be applied to the DUT. Alternatively, the client device may determine the DUT failed the test and send an indication to the host device to discard the DUT, or send an indication of a different test to try. If the test decision includes running a new test, the host device may store a test image of the new test in the shared memory (e.g., in a placeholder location) and perform the handshake with the DUT to inform the test interface of the DUT to resume and proceed to the next test image. For instance, test software on the host device may write “1111” to a PCIE register to indicate the test interface/logic on the DUT can resume.

In some examples, the system(s) of the present disclosure may include techniques for converting packetized test data to on-chip test data. For instance, the test interface (also referred to herein as “test hardware”) on the DUT may receive the test data in functional packetized formats from PCIe (or any other functional interface used for data communication). That is, the test interface of the DUT may obtain, using the functional interface, a series of data packets including test data for an ATE test applied to the DUT. Once the test data reaches a sequencer of the test interface, the test data may be put through security checks to authenticate (and decrypt, if needed) the incoming test data. The test data (e.g., verified data) may be transferred to the test logic. The test logic may decode and unpack the incoming data into atomic blocks. For instance, the test logic and/or test interface may update the test data from its packetized format to a raw data format corresponding to a format of input data received using an input pin of the DUT (e.g., the test logic may extract the test data from the packets so the test data appears the same as it would if the test data were applied by the ATE directly to the I/O pins of the DUT). In some examples, the atomic block size may be set to any length for a given project. The larger the block size, the faster the logic may operate. For example, assume the block sizes are 2-bytes (2 B) wide and the test interface exposes a total of 64 blocks to be connected to downstream test logic. Out of these 64 blocks, any of them may be assigned to any test functionality and/or test network (e.g., SCAN test network, JTAG test network, etc.). For example, 60 blocks may be assigned/connected to SCAN test data, while 4 may be assigned/connected to JTAG data. By assigning the test data to the atomic blocks, the test logic/test interface may apply the test data in the raw data format to a specific portion of the DUT that is to execute the ATE test.

Regardless of how the blocks are physically connected or used, the incoming packetized data (e.g., headers of the packets) indicates to the test interface where the raw data should be redirected. For instance, the test interface may read the headers of the packets to determine a specific portion (e.g., test network, etc.) of the DUT to apply the test data to. In some examples, while one test image may send its data to blocks 1, 2, 3, 6, 7, and 10, another test image may send its data to all the first 60 blocks. This flexibility may allow the test software on the host device to use the available functional bandwidth in the most optimum way for a given test.

In the opposite direction, the reverse may be done. Following the same example as above, for instance, 64 blocks may be exposed to receive test data from the chip, and 60 of them may be used for the SCAN test data, while 4 may be used for JTAG return data. As in the case of input data, the incoming packets tell the test interface which blocks should be packetized and sent back to the shared memory.

Because functional interfaces are not always deterministic, they may not guarantee that input data will always be available, or that output data may always be accepted. This means that the test hardware on the DUT may need to have a mechanism to handle backpressure in data channels. This may be accomplished by precise control of test clocks based on data flow conditions.

For instance, as another example, 8 blocks may be connected to SCAN network, while one block may be connected to JTAG network. Each test network (SCAN or JTAG) may have its own clock control logic. This logic may monitor the condition of data paths on upstream logic (test hardware side) to determine whether to allow test clocks to toggle or to stop the clocks. If there is a free data flow (both input and output directions may be open), the clocks may be allowed to toggle. If there is a stall on either the input or output direction, the clocks may be stopped until data flow is opened again. In some instances, the clock control logic may stop and restart the clocks in the whole die in a cycle accurate manner (e.g., all data transactions may be stopped or restarted at the same cycle over the complete die).

As noted above and herein, the handshake mechanisms described herein may enable various debug and failure analysis features of ATE to be applied to DUTs using packetized test formats. In some instances, such as for debug and diagnosis purposes, burn-in runs, etc., it may be desirable to send a stream of repeating patterns to the downstream test logic on the DUT. Although these repeating patterns may be sent from the functional interface, this may not be the most efficient way of providing the required data. Additionally, functional interfaces may not guarantee a continuous data stream because of uncertainty in the data channel characteristics (e.g., PCIe data streams are indeterministic).

In one aspect of the present disclosure, the test interface on the DUT may support driving repeating data streams to the test logic. The test interface may use an internal storage (e.g., SRAM) to store a repeating bitstream of N cycles (e.g., N=32 cycles). The bitstream may be repeated for a fixed number of cycles or until the test software on the host device asks to stop sending data. If a fixed number of repetitions are needed, repeat count may be passed to the test interface via packetized data. If repetition count is not known in advance, the packet may ask the test interface to continue driving the bitstream data until the host device sends a request to stop. In such an example, the test interface may use the handshake mechanisms disclosed herein to indicate to the test software on the host device that bitstream repetitions have started, and then listen for a stop signal from the test software.

Additionally, in some instances, some failure analysis runs may require looping over a complete test pattern continuously. In such cases, the system(s) of the present disclosure may support these types of loops by creating test images that create a loopback to one of the earlier images. For instance, in the chain of packets, one of the packets may be marked as a “loop end point.” Once the test interface starts executing test images, the test interface may enter an intentional and expected infinite loop to continuously execute the data in this loop, while also monitoring a stop signal from the test software on the host device. Once the stop signal is received (e.g., using the handshake mechanism or other means of data communication), the test interface may exit the loop and enter the pause state the next time it reaches the packet marked as the loop end point.

In some cases, certain debug and failure analysis runs may require stopping test execution at specific test cycles. The system(s) of the present disclosure, in some examples, may support this functionality—which may not be done easily when the data flows through an indeterministic functional interface—by using input packets to specify the exact cycle number where the test execution should be paused. Based on the input packet, the test interface may stop the test execution at the specified cycle and use the handshake mechanism to indicate to the test software on the host device that the test hardware is in a pause state. This process may be repeated as many times as necessary.

In some examples, during test execution, external software or debug tools (e.g., on the host device and/or client device) may have no indication of what is happening in the DUT. As such, the system(s) of the present disclosure, in some instances, may enable debug hooks that may provide live data to external entities. For instance, the test interface may be configured to send heartbeat pulses to a specified DUT pin every N cycles of test data execution. In this way, external agents may monitor the pulses on the DUT pin to understand at which point the test execution is at that point in time. Additionally, or alternatively, the test interface may, in some examples, be configured to send pulses to a specified DUT pin whenever a programmable internal condition is met (e.g., scan_enable transition or error indicator from an internal node).

As described above, and in various examples described herein, the test interface on the DUT may send all the data/results coming back from the test networks to the shared memory between the DUT and the host device. However, the system(s) disclosed herein may additionally, or alternatively, configure the test interface to send only a portion of the data, or no data at all, to the shared memory. As a first example, if finding/testing the defective regions in the DUT does not require the raw scan data output, the test interface may be programmed not to send any data for specific images. In this case, raw scan data may be dumped only when detailed failure analysis is needed. As a second example, even when detailed failure analysis may be needed, the shared memory may not have sufficient space to store all the raw scan output data. In this case, a specific section of the raw output data may be dumped to system memory. In such an example, the host device may specify in the test image a start point and an end point for data dumping.

The systems and methods described herein may be used to test electronic components used in a variety of applications including, without limitation, non-autonomous vehicles or machines, semi-autonomous vehicles or machines (e.g., in one or more adaptive driver assistance systems (ADAS)), autonomous vehicles or machines, piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets, cloud computing and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems implementing language models, such as large language models (LLMs), vision language models (VLMs), and/or multi-modal language models, systems implementing one or more vision language models (VLMs), systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems for performing generative AI operations, systems implemented at least partially using cloud computing resources, and/or other types of systems.

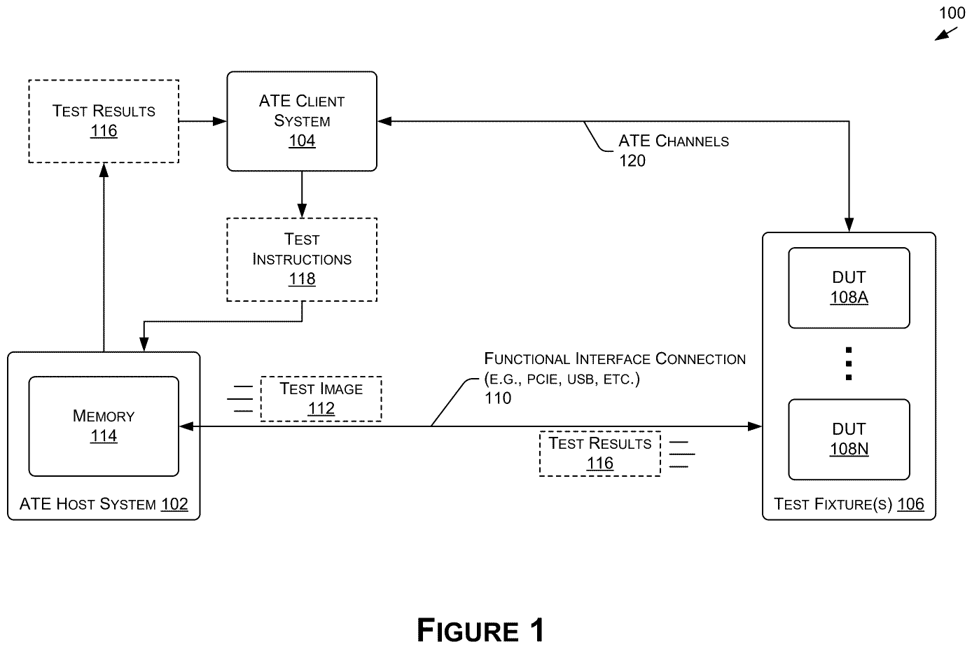

With reference to FIG. 1, FIG. 1 illustrates an example of a system 100 that may be used to apply packet-based ATE tests through high-speed interfaces, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

The system 100 may include an ATE host system 102, an ATE client system 104, and one or more test fixtures 106 for one or more DUTs 108A-108N (where N represents any number). The ATE host system 102 may communicate with the one or more DUTs 108A-108N (hereinafter referred to as “DUT(s) 108”) using a functional interface connection 110. The DUT(s) 108 may use the functional interface connection 110 to obtain test images, such as the test image 112, from the memory 114 of the ATE host system 102. Additionally, the DUT(s) 108 may use the functional interface connection 110 to send test results 116 to the ATE host system 102. For instance, the DUT(s) 108 may use the functional interface connection 110 to write the test results 116 in the memory 114.

In some examples, the ATE client system 104 may determine the specific test that is to be executed and send test instructions 118 to the ATE host system 102. The test instructions 118 may indicate the specific test that is to be applied to the DUT(s) 108. The ATE host system 102 may cause a test image 112 of the test to be sent as packetized data to the DUT(s) 108 via the functional interface connection 110, and logic on the DUT(s) 108 may convert the packetized data to raw data that is representative of raw test inputs applied directly to input pins of the DUT(s) 108 by the ATE client system 104 using ATE channels 120. The logic on the DUT(s) 108 may further packetize results of the test and send the packetized test results 116 back to the ATE host system 102 via the functional interface connection 110. The ATE host system 102 may forward the test results 116 to the ATE client system 104, and the ATE client system 104 may determine whether the DUT(s) 108 passed the test, as well as next actions to be taken (e.g., discard the DUT(s) 108, apply additional tests, etc.).

In some examples, to be able to run traditional ATE tests, defect-free test logic may be necessary. For instance, if the test logic itself is defective, the DUT(s) 108 may immediately fail ATE testing and get discarded. In some instances, if PCIe and/or other functional interface connections 110 are used as a data interface, the physical layer (UPHY) and a portion of the PCIe logic may be used for packetized testing and they may need to be defect-free. In traditional ATE testing, if there are defects in the test logic, test responses may fail. In the case of packet-based testing use cases, if there are defects in the PCIe logic or UPHY, the defects may cause hang issues on the ATE host system 102 connected to the ATE client system 104.

As such, the system(s) of the present disclosure may provide a backbone test, that may be run before packet-based testing may start. The backbone test may use, in some instances, traditional ATE setups with minimal numbers of pins. In some examples, UPHY/PCIe pins may also be used for this purpose. The packet-based test control logic and/or supporting PCIe logic may be wrapped into a circuit block, which may be isolated from other logic. The backbone logic may be completely tested before starting packet-based testing to minimize or eliminate the risk of stall conditions that can increase the overall test-time. For purposes of the backbone test, as well as other purposes, the test fixture(s) 106 may include, in some examples, one or more relays for selecting between packetized data and ATE channels.

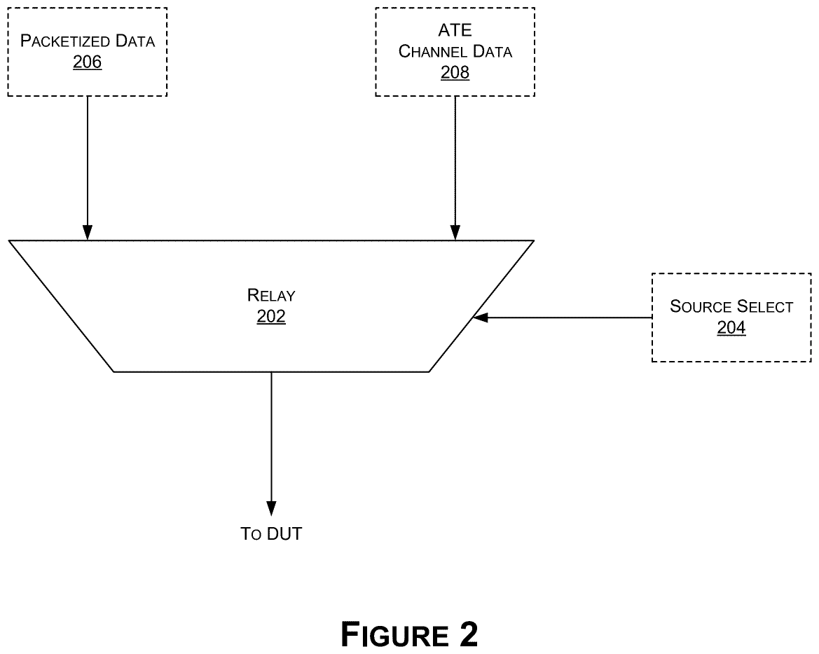

For instance, FIG. 2 illustrates an example of a relay 202 that may be used to select whether to apply packetized data or ATE channel data, in accordance with some embodiments of the present disclosure. For instance, based on a source select signal 204 applied to the relay 202, data flowing out of the relay 202 and to the DUT may be switched between packetized data 206 and ATE channel data 208. In some examples, the packetized data 206 may flow from the ATE host system 102 via the functional interface connection 110, while the ATE channel data 208 may flow from the ATE client system 104 via the ATE channels 120. In various examples, the relay 202 may be used to perform the backbone test described above and herein, as well as for other operations where switching between packet-based and raw data signals may be desired.

In various examples, ATE testing may not be composed of a single stream of test-vectors. Instead, ATE testing may include various test types and corresponding test-vectors. As such, ATE testing may be generally described as a decision tree, where a result(s) of a previous test(s) is used for deciding which test to run next. In some examples, the system(s) of the present disclosure may support a handshake mechanism (e.g., pause/resume handshake) for optimal test flow and to eliminate any risk of race conditions.

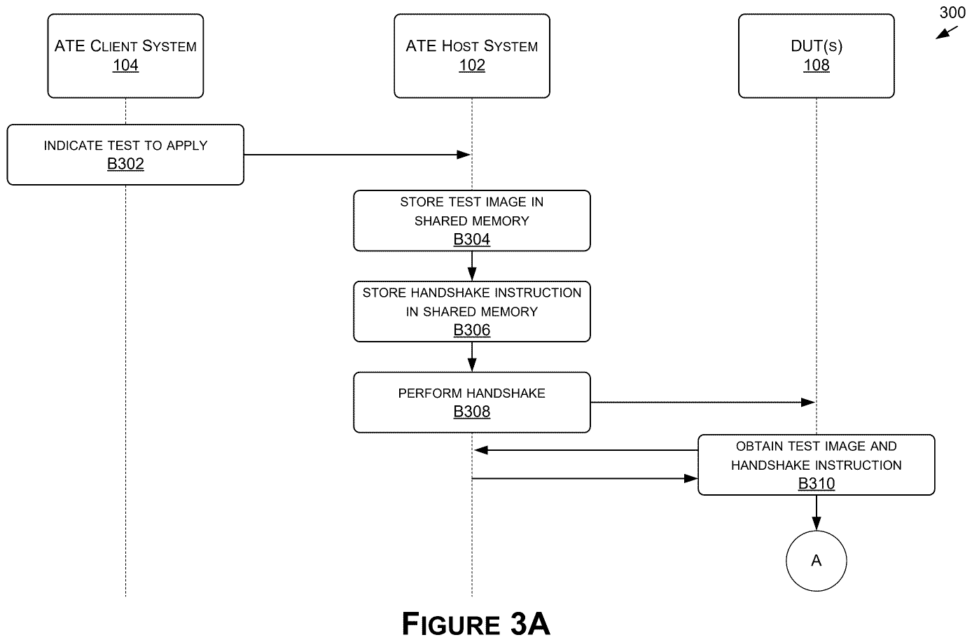

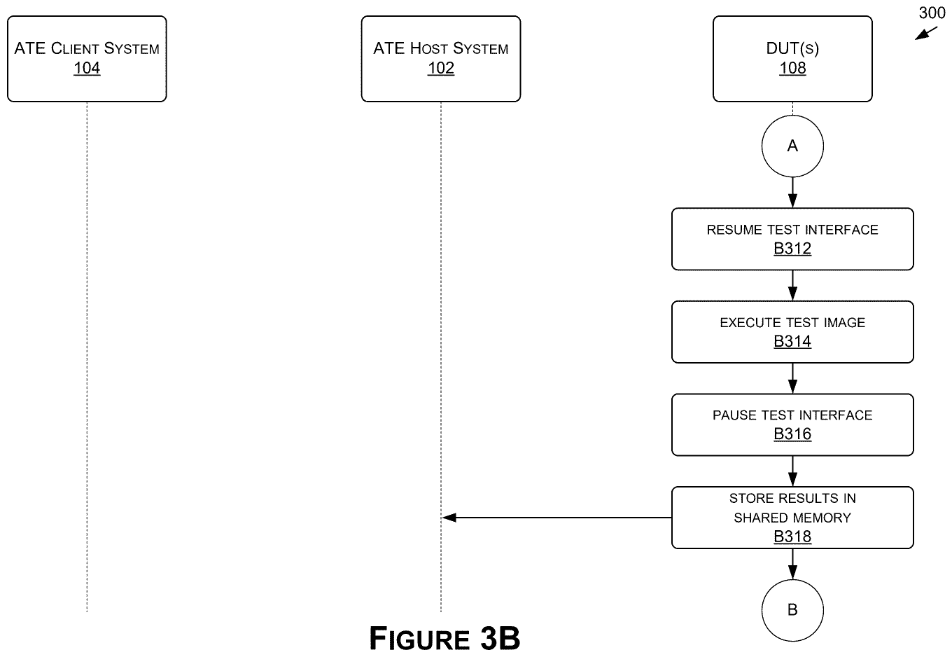

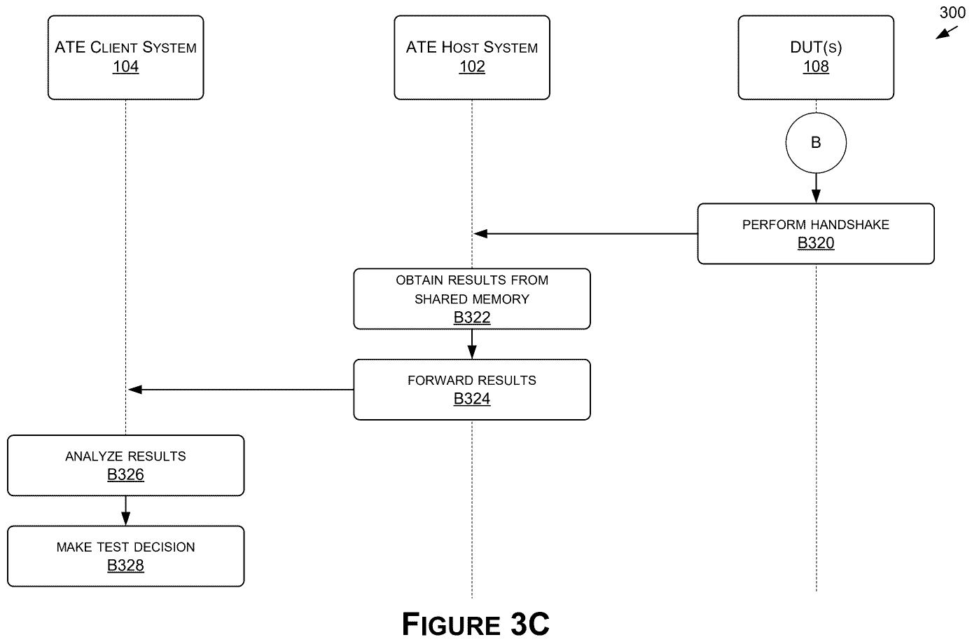

For instance, FIGS. 3A-3C illustrate a data flow diagram of an example of a handshake process 300 that may be performed to apply packet-based ATE tests to a DUT, in accordance with some embodiments of the present disclosure. At block B302, the process 300 includes the ATE client system 104 indicating a test to apply. For instance, the ATE client system 104 may send the test instructions 118 to the Ate host system 102, and the test instructions may indicate the test the ATE host system 102 is to send to the DUT(s) 108.

At block B304, the process 300 may include the ATE host system 102 storing a test image in a shared memory. For instance, based at least on receiving the indication of the test to be applied, the ATE host system 102 may identify the test image (e.g., test file, package, etc.) for the test and store the test image in the memory 114. Additionally, or alternatively, the ATE host system 102 may identify the storage location of the test image. That is, the test image may always be stored in the shared memory, and based on the test instructions received from the ATE client system 104 the ATE host system 102 may identify the storage location so that it may point the DUT(s) 108 to the storage location for obtaining the test image.

At block B306, the process 300 may include the ATE host system 102 storing a handshake instruction in the shared memory. For instance, the ATE host system 102 may indicate in the test image 112 that the test hardware/logic on the DUT(S) 108 should go into “pause” mode after completing the executing of the corresponding test image 112. Additionally, in some examples, the ATE host system 102 may, within the same test image 112, also indicate the memory location that shall be used for the pause/resume handshake, along with a signature that should be written to the specified memory location. In other words, the ATE host system 102 may modify the test image 112 so that the DUT(s) 108—or the test interface/logic on the DUT(s) 108—knows to enter pause mode after executing the test image 112, as well as to inform the DUT(s) 108 of the memory location and signature the DUT(s) 108 is to use for performing the handshake. In at least one example, handshake signatures may be selected to have error correcting codes. In doing so, the system(s) of the present disclosure may guarantee more reliable operation, since soft-errors and single-bit upsets may not cause incorrect behavior.

At block B308, the process 300 may include the ATE host system 102 performing a handshake. For instance, based at least on the ATE host system 102 storing the test image in the memory, the ATE host system may perform the pause/resume handshake to cause the test interface on the DUT(s) 108 to resume and begin executing the test image. In some examples, the ATE host system 102 may perform the handshake by writing a signature or string of bits (e.g., “1111”) to an addressable register associated with the functional interface, or to a specific storage location in the memory. For instance, as an example of using the handshake mechanism, the ATE host system 102 and the DUT(s) 108 may use and monitor a specific storage location in the shared memory 114 for certain signatures. As one example, the ATE host system 102 may write “1111” to the storage location to perform a resume handshake, and write “1010” to the storage location to perform a pause handshake. Similarly, the DUT(s) may write “1001” to the storage location to indicate it is in the paused state, and write “0110” to the storage location to indicate it is in a resumed or active state. However, these are just a couple of examples, and in additional or alternative examples, any common storage locations and/or any signatures can be used for the handshakes.

At block B310, the process 300 may include the DUT(s) 108 obtaining the test image and handshake instruction. For instance, based at least on the ATE host system 102 performing the handshake, the DUT(s) may obtain the test image and the handshake instruction (e.g., from the shared memory) using the high-speed functional interface. In some examples, the handshake instruction may indicate a storage location of the shared memory and a signature to write at the storage location to perform the handshake. Additionally, the handshake instruction may indicate the test interface on the DUT(s) 108 is to enter the pause state after executing the test image, and the handshake may be used as evidence to indicate the test interface is, in fact, in the paused state and has executed the test image.

At block B312, the process 300 may include the DUT(s) 108 resuming a test interface. For instance, based at least on the ATE host systems 102 performing the handshake in block B308, the DUT(s) 108 may resume the test interface on the DUT(s) 108. At block B314, the process 300 may include the DUT(s) 108 executing the test image. For instance, after resuming the test interface, the test interface may execute the test image obtained by the DUT(s) 108. In some examples, the test interface may execute the test image by extracting test data from data packets used to send the test image over the high-speed functional interface connection, and the test data may be applied to one or more test networks (e.g., SCAN test network, JTAG test network, etc.) within the DUT(s) 108.

At block B316, the process 300 may include the DUT(s) 108 pausing the test interface. For instance, based at least on the handshake instructions, the DUT(s) 108 may pause the test interface subsequent to executing the test image and/or subsequent to writing the test results in the shared memory. At block B318, the process 300 may include the DUT(s) 108 storing results of the test in the shared memory. For instance, the DUT(s) 108 may store the test results in the memory 114 of the ATE host system 102. In some examples, the test results may be stored in the memory at the same location used for the pause handshake specified by the ATE host system 102 in the test image 112.

At block B320, the process 300 may include the DUT(s) 108 performing a handshake. For instance, the DUT(s) 108 may write the specified signature to the specified memory location from the test image 112, thereby indicating that the image execution is complete and the test logic/interface has entered the pause state waiting for further instructions from the ATE host system 102. That is, since the current test image 112 requested the pause, the test interface of the DUT(s) 108 may activate/enter the pause state before starting to read the next test image 112, and the test interface may enter the pause state after the test results packet(s) is written back to the system memory. By writing the specified signature to the specified memory locations, the DUT(s) 108 may perform the handshake and the ATE host system 102 may know that the results are stored at the memory location (or another specified memory location).

At block B322, the process 300 may include the ATE host system 102 obtaining the results from the shared memory. For instance, based at least on the DUT(s) 108 performing the handshake, the ATE host system 102 may obtain the test results 116 from the memory 114. In some examples, the test results 116 may be stored in the memory 114 at the specified location. At block B324, the process 300 may include the ATE host system 102 forwarding the results to the ATE client system 104. For instance, the ATE host system 102 may forward the test results 116 to the ATE client system 104, which may be running the ATE test method.

At block B326, the process 300 may include the ATE client system 104 analyzing the results. For instance, the ATE client system 104 may analyze the test results 116 to determine whether the DUT(s) 108 passed or failed the test. At block B328, the process 300 may include the ATE client system 104 making a test decision. For instance, based at least on analyzing the results and determining whether or not the DUT(s) 108 passed or failed the test, the ATE client system 104 may make one or more test decisions. The test decisions may include determining one or more additional tests to be applied to the DUT(s) 108, determining whether the DUT(s) 108 should be discarded as being defective, determining whether the DUT(s) 108 should be released from testing as fully or partially operational, etc.

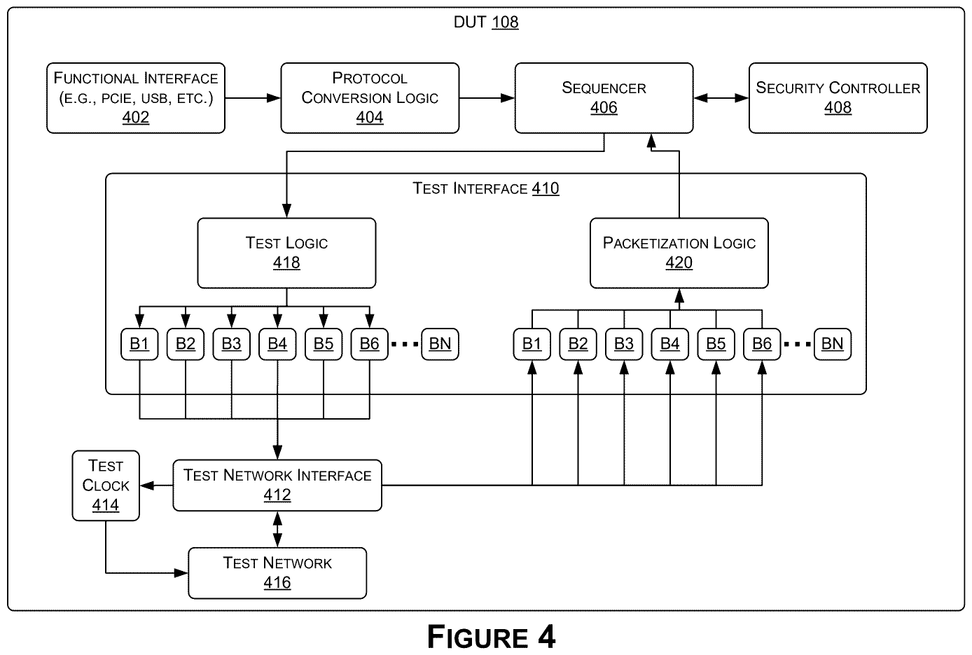

As noted above and herein, the handshake mechanisms and similar processes to the process 300 described herein may enable various debug and failure analysis features of ATE to be applied to the DUT(s) 108 using packetized test formats. In some instances—such as for debug and diagnosis purposes, burn-in runs, etc.—it may be desirable to send a stream of repeating patterns to the downstream test logic (e.g., the test interface 410 or test logic 418 described in FIG. 4 below) on the DUT(s) 108. Although these repeating patterns may be sent from the functional interface connection 110, this may not be the most efficient way of providing the required data. Additionally, functional interface connections may not guarantee a continuous data stream because of uncertainty in the data channel characteristics (e.g., PCIe data streams are indeterministic).

In one aspect of the present disclosure, the test interface 410 or test logic 418 on the DUT 108 may support driving repeating data streams to the test logic. The test interface may use an internal storage (e.g., SRAM) to store a repeating bitstream of N cycles (e.g., N=32 cycles). The bitstream may be repeated for a fixed number of cycles or until the test software on the ATE host system 102 asks to stop sending data. If a fixed number of repetitions are needed, repeat count may be passed to the test interface via packetized data. If repetition count is not known in advance, the packet may ask the test interface to continue driving the bitstream data until the ATE host system 102 sends a request to stop. In such an example, the test interface may use the handshake mechanisms disclosed herein to indicate to the test software on the ATE host system 102 that bitstream repetitions have started, and then listen for a stop signal from the test software.

Additionally, in some instances, some failure analysis runs may require looping over a complete test pattern continuously. In such cases, the system(s) of the present disclosure may support these types of loops by creating test images that create a loopback to one of the earlier images. For instance, in the chain of packets, one of the packets may be marked as a “loop end point.” Once the test logic 418 starts executing test images, the test logic 418 may enter an intentional and expected infinite loop to continuously execute the data in this loop, while also monitoring a stop signal from the test software on the ATE host system 102. Once the stop signal is received (e.g., using the handshake mechanism or other means of data communication), the test interface 410 may cause the test logic 418 to exit the loop and enter the pause state the next time it reaches the packet marked as the loop end point.

In some cases, certain debug and failure analysis runs may require stopping test execution at specific test cycles. The system(s) of the present disclosure, in some examples, may support this functionality—which may not be done easily when the data flows through an indeterministic functional interface connection 110—by using input packets to specify the exact cycle number where the test execution should be paused. Based on the input packet, the test interface may stop the test execution at the specified cycle and use the handshake mechanism to indicate to the test software on the ATE host system 102 that the test hardware is in a pause state. This process may be repeated as many times as necessary.

In some examples, during test execution, external software or debug tools (e.g., on the ATE host system 102 and/or ATE client system 104) may have no indication of what is happening in the DUT(s) 108. As such, the system(s) of the present disclosure, in some instances, may enable debug hooks that may provide live data to external entities. For instance, the test interface may be configured to send heartbeat pulses to a specified DUT(s) 108 pin every N cycles of test data execution. In this way, external agents may monitor the pulses on the DUT(s) 108 pin to understand at which point the test execution is at that point in time. Additionally, or alternatively, the test interface may, in some examples, be configured to send pulses to a specified DUT(s) 108 pin whenever a programmable internal condition is met (e.g., scan_enable transition or error indicator from an internal node).

As described above, and in various examples described herein, the test interface on the DUT 108 may send all the data/results coming back from the test networks to the memory 114 between the DUT 108 and the ATE host system 102. However, the system(s) disclosed herein may additionally, or alternatively, configure the test interface to send only a portion of the data, or no data at all, to the memory 114. As a first example, if finding/testing the defective regions in the DUT 108 does not require the raw scan data output, the test interface may be programmed not to send any data for specific images. In this case, raw scan data may be dumped only when detailed failure analysis is needed. As a second example, even when detailed failure analysis may be needed, the memory 114 may not have sufficient space to store all the raw scan output data. In this case, a specific section of the raw output data may be dumped to system memory. In such an example, the ATE host system 102 may specify in the test image 112 a start point and an end point for data dumping.

In some examples, the system(s) of the present disclosure may include techniques for converting packetized test data to on-chip test data. For instance, FIG. 4 illustrates an example data flow of packetized test data within a DUT, in accordance with some embodiments of the present disclosure. A shown, the DUT 108 may include a functional interface 402, protocol conversion logic 404, a sequencer 406, a security controller 408, a test interface 410, a test network interface 412, a test clock 414, and a test network 416.

The functional interface 402 may include any HSIO interface, such as a PCIe interface, a USB interface, or any other hardware interface for data communication. The DUT 108 may use the functional interface 402 to obtain the packetized test images containing the test data from the host ATE system 102. The test interface 410 (also referred to herein as “test hardware”) on the DUT 108 may receive the test data in functional packetized formats from the functional interface 402. That is, the test interface 410 of the DUT 108 may obtain, using the functional interface 402, a series of data packets including test data for an ATE test applied to the DUT 108. Once the test data reaches the sequencer 406 of the test interface 410, the test data may be put through security checks using the security controller 408 to authenticate (and decrypt, if needed) the incoming test data. The test data (e.g., verified test data) may be transferred to test logic 418 on the test interface 410. The test logic 418 may decode and unpack the incoming data into atomic blocks “B1-BN” (where “N” may represent any number of atomic blocks). For instance, the test logic 418 and/or test interface 410 may update the test data from its packetized format to a raw data format corresponding to a format of input data received using an input pin of the DUT 108 (e.g., the test logic 418 may extract the test data from the packets so the test data appears the same as it would if the test data were applied by the ATE directly to the I/O pins of the DUT 108). In some examples, the atomic block size may be set to any length for a given project. The larger the block size, the faster the logic may operate. For example, assume the block sizes are 2-bytes (2 B) wide and the test interface 410 exposes a total of 64 blocks to be connected to downstream test logic. Out of these 64 blocks, any of them may be assigned to any test functionality and/or test network 416 (e.g., SCAN test network, JTAG test network, etc.). In the example of FIG. 4 6 of the atomic blocks B1-B6 are assigned to the test network 416. By assigning the test data to the atomic blocks, the test logic 418/test interface 410 may apply the test data in the raw data format to a specific portion of the DUT 108 that is to execute the ATE test. For instance, the test network 416 may correspond to a SCAN test network and the test network interface 412 may correspond to an interface associated with the SCAN test network, in some examples. Additionally, the test clock 414 may correspond to a clock associated with the SCAN test network (or any other test network).

Regardless of how the blocks are physically connected or used, the incoming packetized data (e.g., headers of the packets) indicates to the test logic 418 where the raw data should be redirected. For instance, the test logic 418 may read the headers of the packets to determine a specific portion (e.g., test network, etc.) of the DUT 108 to apply the test data to. In some examples, while one test image may send its data to blocks B1-B6, another test image may send its data to all the blocks. This flexibility may allow the test software on the ATE host system 102 to use the available functional bandwidth in the most optimum way for a given test.

In the opposite direction, the reverse may be done. Following the same example as above, for instance, 64 blocks may be exposed to receive test data from the chip, and blocks B1-B6 may be used for the test network 416 data. As in the case of input data, the incoming packets tell the packetization logic 420 of the test interface 410 which blocks should be packetized and sent back to the memory 114. The packetization logic 420 may then convert the data from the blocks back to packetized data format to send back to the ATE host system 102 using the functional interface 402.

Because the functional interface 402 and its corresponding connections may not always be deterministic, they may not guarantee that input data will always be available, or that output data may always be accepted. This means that the test hardware on the DUT 108 may need to have a mechanism to handle backpressure in data channels. This may be accomplished by precise control of the test clock 414 based on data flow conditions.

For instance, as another example, the six blocks B1-B6 may be connected to the test network 416. The test network 416 may have its own clock control logic (e.g., test clock 414). This logic may monitor the condition of data paths on upstream logic (test hardware side) to determine whether to allow the test clock 414 to toggle or to stop the test clock 414. If there is a free data flow (both input and output directions may be open), the test clock 414 may be allowed to toggle. If there is a stall on either the input or output direction, the test clock 414 may be stopped until data flow is opened again. In some instances, the clock control logic may stop and restart the test clocks in the whole die (e.g., DUT 108) in a cycle accurate manner (e.g., all data transactions may be stopped or restarted at the same cycle over the complete die).

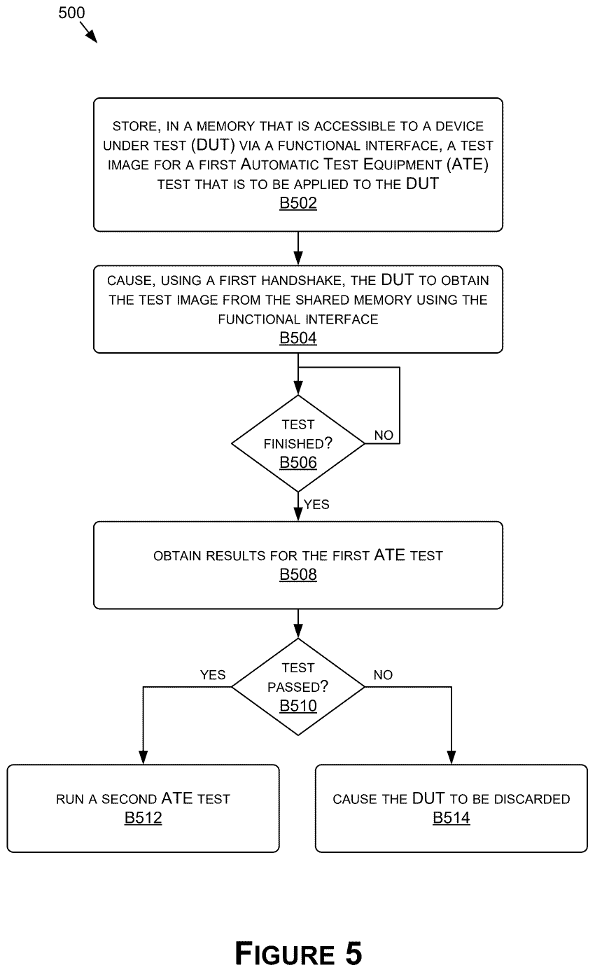

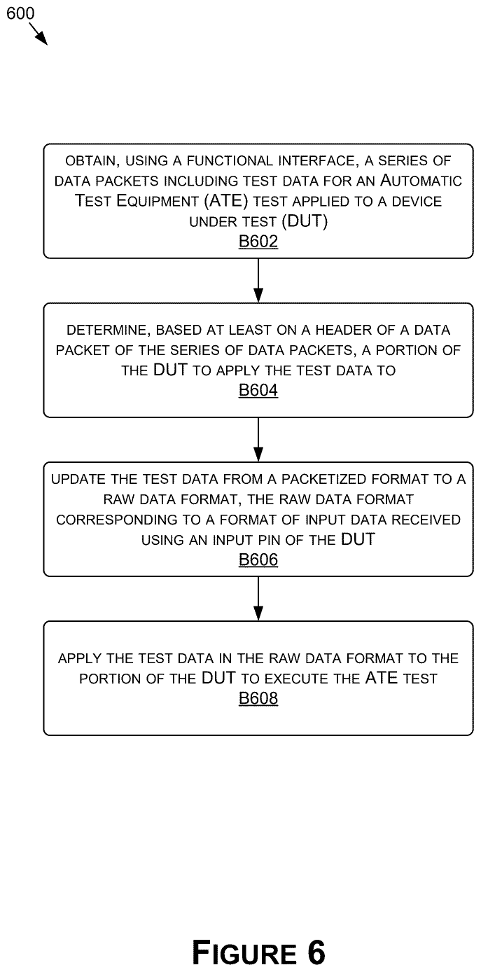

Now referring to FIGS. 5 and 6, each block of methods 500 and 600, described herein, comprises a computing process that may be performed using any combination of hardware, firmware, and/or software. For instance, various functions may be carried out by a processor executing instructions stored in memory. The methods may also be embodied as computer-usable instructions stored on computer storage media. The methods may be provided by a standalone application, a service or hosted service (standalone or in combination with another hosted service), or a plug-in to another product, to name a few. In addition, methods 500 and 600 are described, by way of example, with respect to the system of FIG. 1. However, these methods may additionally or alternatively be executed by any one system, or any combination of systems, including, but not limited to, those described herein.

FIG. 5 is a flow diagram illustrating an example of a method 500 for using handshakes to optimize ATE test flows and pause/resume a test interface executing on a DUT, in accordance with some embodiments of the present disclosure. The method 500, at block B502, includes storing, in a memory that is accessible to a DUT via a functional interface, a test image for a first Automatic Test Equipment (ATE) test that is to be applied to the DUT. For instance, the ATE host system 102 may store, in the memory 114, the test image 112 for the first ATE test that is to be applied to the DUT(s) 108. In some examples, the memory 114 may be accessible (e.g., read/write capable) to the DUT(s) 108 via the functional interface connection 110.

The method 500, at block B504, includes causing, using a first handshake, the DUT to obtain the test image from the shared memory using the functional interface. For instance, the ATE host system 102 may perform the first handshake to cause the DUT(s) 108 to obtain the test image 112 from the memory 114 using the functional interface connection 110. In some examples, the ATE host system 102 may perform the first handshake by writing a signature to a shared memory location, such as writing a “resume” signature to the memory 114 and/or an addressable register space of the functional interface (e.g., BAR addressable register space of a PCIe interface).

The method 500, at block B506, includes determining whether the DUT finished execution of the first ATE test. For instance, the ATE host system 102 may determine whether the DUT(s) 108 finished execution of the first ATE test based at least on determining whether the DUT(s) 108 performed a second handshake. For example, within the test image handshake instructions may have been stored for the DUT(s) 108 to perform a handshake and enter a pause state subsequent to finishing execution of the test image. As such, the DUT(s) 108 may perform the handshake operation as an indication that test execution is complete, and the ATE host system 102 may use the handshake status to determine whether the test has been completed. Once the determination is made that the test has been completed, the method 500 may proceed to block B508.

The method 500, at block B508, includes obtaining results for the first ATE test. For instance, based at least on determining that the DUT(s) 108 performed the handshake operations to indicate the test is completed, the ATE host system 102 may obtain the results for the first ATE test from the memory 114, or from communication with the DUT(s) 108. In some examples, the ATE host system 102 may obtain the test results via the functional interface connection 110, or via the memory 114. For instance, the DUT(s) 108 may use the functional interface connection 110 to write/store the test results in the memory 114.

The method 500, at block B510, includes determining whether the DUT passed or failed the first ATE test. For instance, the ATE host system 102 may forward the test results 116 to the ATE client system 104 for evaluation, and the ATE client system 104 may determine whether or not the DUT(s) 108 passed or failed the first ATE test. If the DUT(s) 108 passed the first ATE test, the method 500 may proceed to block B512. However, if the DUT(s) 108 failed the first ATE test, the method 500 may proceed to block B514.

The method 500, at block B512, includes running a second ATE test. For instance, if the DUT(s) 108 passed the first ATE test, the ATE client system 104 may send the test instructions 118 indicating the second ATE test that is to be ran, and the ATE host system 102 may determine a second test image for the second ATE test, store the second test image in the memory 114, and cause the DUT(s) 108 to obtain the second test image. In some examples, the second ATE test may include one or multiple tests. In some instances, the second ATE test may be ran in scenarios where the DUT(s) 108 failed (e.g., partially failed, etc.) the first ATE test, but the DUT(s) 108 does not warrant being discarded. In some instances, if the DUT(s) pass all the tests, the system(s) may generate an indication that the DUT(s) passed and cause presentation of the indication on a user interface or other computing device, cause a removal of the DUT(s) from the test fixture(s) associated with the ATE systems (e.g., using a robot, machine, etc.), or perform any other operations.

The method 500, at block B514, includes causing the DUT to be discarded. For instance, if the DUT(s) 108 failed the first ATE test, the ATE client system 104 may determine the DUT(s) 108 should be discarded (e.g., as being a defective device), and the ATE client system 104 and/or the ATE host system 102 may cause the DUT(s) 108 to be discarded, or refrain from continuing testing. In some examples, causing the DUT to be discarded may include physically discarding the DUT(s) 108, causing a removal and/or removing the DUT(s) 108 from the test fixture(s) 106 (e.g., sending instructions to a robot or machine to cause removal of the DUT(s)), or outputting an indication of the failure and that the chip should be discarded.

FIG. 6 is a flow diagram illustrating an example of a method 600 for using packetized test data to apply an ATE test to a portion of a DUT, in accordance with some embodiments of the present disclosure. The method 600, at block B602, includes obtaining, using a functional interface, a series of data packets including test data for an ATE test applied to a DUT. For instance, the test interface 410 of the DUT 108 may obtain the series of data packets including the test data for the ATE test using the functional interface 402. The functional interface may include, in some instances, a PCIe interface, a USB interface, or any other HSIO interface.

The method 600, at block B604, includes determining, based at least on a header of a data packet of the series of data packets, a portion of the DUT to apply the test data to. For instance, the test interface 410 and/or the test logic 418 may determine the portion of the DUT 108 to apply the test data to based at least on the header of the data packet of the series of data packets. In some examples, the portion of the DUT may correspond to a specific test network of the DUT 108, such as the test network 416.

The method 600, at block B606, includes updating the test data from a packetized format to a raw data format, the raw data format corresponding to a format of input data received using an input pin of the DUT. For instance, the test logic 418 and/or the test interface 410 may update the test data from the packetized format to the raw data format. In this way, when the test data is applied to the test network 416, the test data may be in the same format as traditional ATE inputs that may be applied to the test network 416 through input pins of the DUT 108.

The method 600, at block B608, includes applying the test data in the raw data format to the portion of the DUT to execute the ATE test. For instance, the test logic 418 may apply the test data in the raw data format to the portion of the DUT 108 to execute the ATE test. In some examples, the portion of the DUT may correspond to the test network 416 (e.g., a SCAN test network). In some examples, to apply the test data to the portion of the DUT 108, the test logic 418 may assign the test data to one or more of the atomic blocks B1-BN that are assigned to that portion of the DUT 108.

### Example Computing Device

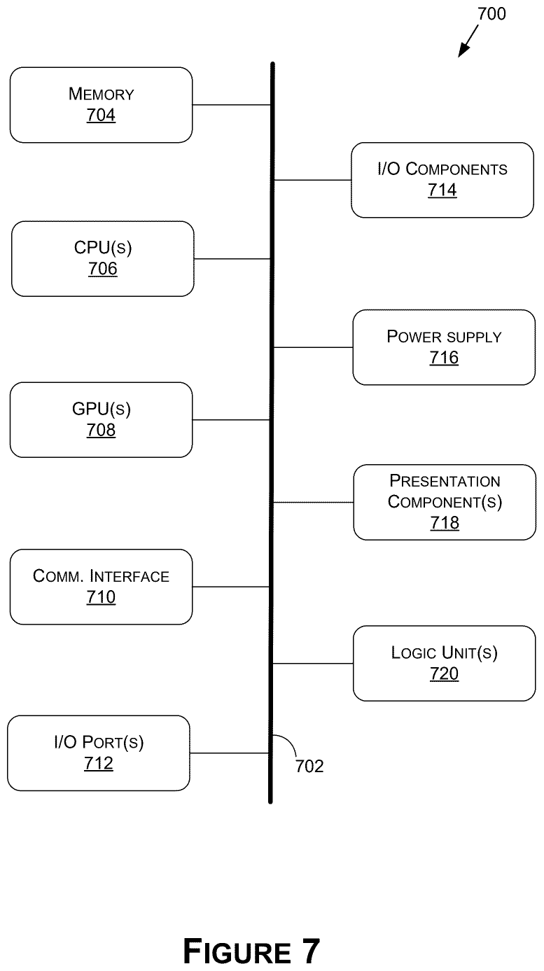

FIG. 7 is a block diagram of an example computing device(s) 700 suitable for use in implementing some embodiments of the present disclosure. Computing device 700 may include an interconnect system 702 that directly or indirectly couples the following devices: memory 704, one or more central processing units (CPUs) 706, one or more graphics processing units (GPUs) 708, a communication interface 710, input/output (I/O) ports 712, input/output components 714, a power supply 716, one or more presentation components 718 (e.g., display(s)), and one or more logic units 720. In at least one embodiment, the computing device(s) 700 may comprise one or more virtual machines (VMs), and/or any of the components thereof may comprise virtual components (e.g., virtual hardware components). For non-limiting examples, one or more of the GPUs 708 may comprise one or more vGPUs, one or more of the CPUs 706 may comprise one or more vCPUs, and/or one or more of the logic units 720 may comprise one or more virtual logic units. As such, a computing device(s) 700 may include discrete components (e.g., a full GPU dedicated to the computing device 700), virtual components (e.g., a portion of a GPU dedicated to the computing device 700), or a combination thereof.

Although the various blocks of FIG. 7 are shown as connected via the interconnect system 702 with lines, this is not intended to be limiting and is for clarity only. For example, in some embodiments, a presentation component 718, such as a display device, may be considered an I/O component 714 (e.g., if the display is a touch screen). As another example, the CPUs 706 and/or GPUs 708 may include memory (e.g., the memory 704 may be representative of a storage device in addition to the memory of the GPUs 708, the CPUs 706, and/or other components). In other words, the computing device of FIG. 7 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 7.

The interconnect system 702 may represent one or more links or busses, such as an address bus, a data bus, a control bus, or a combination thereof. The interconnect system 702 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 706 may be directly connected to the memory 704. Further, the CPU 706 may be directly connected to the GPU 708. Where there is direct, or point-to-point connection between components, the interconnect system 702 may include a PCIe link to carry out the connection. In these examples, a PCI bus need not be included in the computing device 700.

The memory 704 may include any of a variety of computer-readable media. The computer-readable media may be any available media that may be accessed by the computing device 700. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 704 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 700. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 706 may be configured to execute at least some of the computer-readable instructions to control one or more components of the computing device 700 to perform one or more of the methods and/or processes described herein. The CPU(s) 706 may each include one or more cores (e.g., one, two, four, eight, twenty-eight, seventy-two, etc.) that are capable of handling a multitude of software threads simultaneously. The CPU(s) 706 may include any type of processor, and may include different types of processors depending on the type of computing device 700 implemented (e.g., processors with fewer cores for mobile devices and processors with more cores for servers). For example, depending on the type of computing device 700, the processor may be an Advanced RISC Machines (ARM) processor implemented using Reduced Instruction Set Computing (RISC) or an x86 processor implemented using Complex Instruction Set Computing (CISC). The computing device 700 may include one or more CPUs 706 in addition to one or more microprocessors or supplementary co-processors, such as math co-processors.

In addition to or alternatively from the CPU(s) 706, the GPU(s) 708 may be configured to execute at least some of the computer-readable instructions to control one or more components of the computing device 700 to perform one or more of the methods and/or processes described herein. One or more of the GPU(s) 708 may be an integrated GPU (e.g., with one or more of the CPU(s) 706 and/or one or more of the GPU(s) 708 may be a discrete GPU. In embodiments, one or more of the GPU(s) 708 may be a coprocessor of one or more of the CPU(s) 706. The GPU(s) 708 may be used by the computing device 700 to render graphics (e.g., 3D graphics) or perform general purpose computations. For example, the GPU(s) 708 may be used for General-Purpose computing on GPUs (GPGPU). The GPU(s) 708 may include hundreds or thousands of cores that are capable of handling hundreds or thousands of software threads simultaneously. The GPU(s) 708 may generate pixel data for output images in response to rendering commands (e.g., rendering commands from the CPU(s) 706 received via a host interface). The GPU(s) 708 may include graphics memory, such as display memory, for storing pixel data or any other suitable data, such as GPGPU data. The display memory may be included as part of the memory 704. The GPU(s) 708 may include two or more GPUs operating in parallel (e.g., via a link). The link may directly connect the GPUs (e.g., using NVLINK) or may connect the GPUs through a switch (e.g., using NVSwitch). When combined together, each GPU 708 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 706 and/or the GPU(s) 708, the logic unit(s) 720 may be configured to execute at least some of the computer-readable instructions to control one or more components of the computing device 700 to perform one or more of the methods and/or processes described herein. In embodiments, the CPU(s) 706, the GPU(s) 708, and/or the logic unit(s) 720 may discretely or jointly perform any combination of the methods, processes and/or portions thereof. One or more of the logic units 720 may be part of and/or integrated in one or more of the CPU(s) 706 and/or the GPU(s) 708 and/or one or more of the logic units 720 may be discrete components or otherwise external to the CPU(s) 706 and/or the GPU(s) 708. In embodiments, one or more of the logic units 720 may be a coprocessor of one or more of the CPU(s) 706 and/or one or more of the GPU(s) 708.

Examples of the logic unit(s) 720 include one or more processing cores and/or components thereof, such as Data Processing Units (DPUs), Tensor Cores (TCs), Tensor Processing Units(TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 710 may include one or more receivers, transmitters, and/or transceivers that enable the computing device 700 to communicate with other computing devices via an electronic communication network, included wired and/or wireless communications. The communication interface 710 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 720 and/or communication interface 710 may include one or more data processing units (DPUs) to transmit data received over a network and/or through interconnect system 702 directly to (e.g., a memory of) one or more GPU(s) 708.

The I/O ports 712 may enable the computing device 700 to be logically coupled to other devices including the I/O components 714, the presentation component(s) 718, and/or other components, some of which may be built in to (e.g., integrated in) the computing device 700. Illustrative I/O components 714 include a microphone, mouse, keyboard, joystick, game pad, game controller, satellite dish, scanner, printer, wireless device, etc. The I/O components 714 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 700. The computing device 700 may be include depth cameras, such as stereoscopic camera systems, infrared camera systems, RGB camera systems, touchscreen technology, and combinations of these, for gesture detection and recognition. Additionally, the computing device 700 may include accelerometers or gyroscopes (e.g., as part of an inertia measurement unit (IMU)) that enable detection of motion. In some examples, the output of the accelerometers or gyroscopes may be used by the computing device 700 to render immersive augmented reality or virtual reality.

The power supply 716 may include a hard-wired power supply, a battery power supply, or a combination thereof. The power supply 716 may provide power to the computing device 700 to enable the components of the computing device 700 to operate.

The presentation component(s) 718 may include a display (e.g., a monitor, a touch screen, a television screen, a heads-up-display (HUD), other display types, or a combination thereof), speakers, and/or other presentation components. The presentation component(s) 718 may receive data from other components (e.g., the GPU(s) 708, the CPU(s) 706, DPUs, etc.), and output the data (e.g., as an image, video, sound, etc.).

### Example Data Center

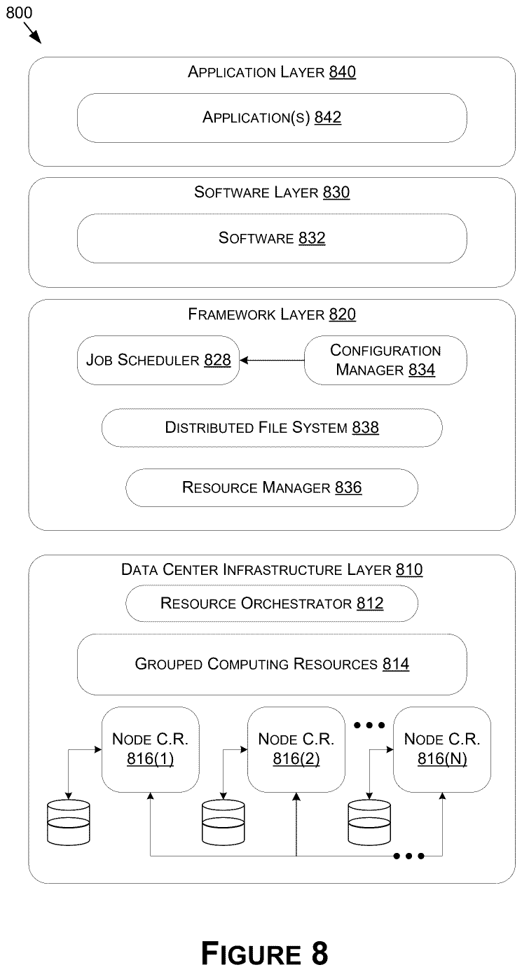

FIG. 8 illustrates an example data center 800 that may be used in at least one embodiments of the present disclosure. The data center 800 may include a data center infrastructure layer 810, a framework layer 820, a software layer 830, and/or an application layer 840.

As shown in FIG. 8, the data center infrastructure layer 810 may include a resource orchestrator 812, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 816(1)-816(N) may correspond to a server having one or more of the above-mentioned computing resources. In addition, in some embodiments, the node C.R.s 816(1)-8161(N) may include one or more virtual components, such as vGPUs, vCPUs, and/or the like, and/or one or more of the node C.R.s 816(1)-816(N) may correspond to a virtual machine (VM).

In at least one embodiment, grouped computing resources 814 may include separate groupings of node C.R.s 816 housed within one or more racks (not shown), or many racks housed in data centers at various geographical locations (also not shown). Separate groupings of node C.R.s 816 within grouped computing resources 814 may include grouped compute, network, memory or storage resources that may be configured or allocated to support one or more workloads. In at least one embodiment, several node C.R.s 816 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 812 may configure or otherwise control one or more node C.R.s 816(1)-816(N) and/or grouped computing resources 814. In at least one embodiment, resource orchestrator 812 may include a software design infrastructure (SDI) management entity for the data center 800. The resource orchestrator 812 may include hardware, software, or some combination thereof.

In at least one embodiment, as shown in FIG. 8, framework layer 820 may include a job scheduler 828, a configuration manager 834, a resource manager 836, and/or a distributed file system 838. The framework layer 820 may include a framework to support software 832 of software layer 830 and/or one or more application(s) 842 of application layer 840. The software 832 or application(s) 842 may respectively include web-based service software or applications, such as those provided by Amazon Web Services, Google Cloud and Microsoft Azure. The framework layer 820 may be, but is not limited to, a type of free and open-source software web application framework such as Apache Spark™ (hereinafter “Spark”) that may utilize distributed file system 838 for large-scale data processing (e.g., “big data”). In at least one embodiment, job scheduler 828 may include a Spark driver to facilitate scheduling of workloads supported by various layers of data center 800. The configuration manager 834 may be capable of configuring different layers such as software layer 830 and framework layer 820 including Spark and distributed file system 838 for supporting large-scale data processing. The resource manager 836 may be capable of managing clustered or grouped computing resources mapped to or allocated for support of distributed file system 838 and job scheduler 828. In at least one embodiment, clustered or grouped computing resources may include grouped computing resource 814 at data center infrastructure layer 810. The resource manager 836 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 838 of framework layer 820. One or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 838 of framework layer 820. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 834, resource manager 836, and resource orchestrator 812 may implement any number and type of self-modifying actions based on any amount and type of data acquired in any technically feasible fashion. Self-modifying actions may relieve a data center operator of data center 800 from making possibly bad configuration decisions and possibly avoiding underutilized and/or poor performing portions of a data center.

The data center 800 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 800. In at least one embodiment, trained or deployed machine learning models corresponding to one or more neural networks may be used to infer or predict information using resources described above with respect to the data center 800 by using weight parameters calculated through one or more training techniques, such as but not limited to those described herein.

In at least one embodiment, the data center 800 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 700 of FIG. 7—e.g., each device may include similar components, features, and/or functionality of the computing device(s) 700. In addition, where backend devices (e.g., servers, NAS, etc.) are implemented, the backend devices may be included as part of a data center 800, an example of which is described in more detail herein with respect to FIG. 8.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 700 described herein with respect to FIG. 7. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

### Example Paragraphs

A. At least one processor comprising processing circuitry to: receive, from an Automatic Test Equipment (ATE) device, an indication of an ATE test to be applied to a device under test (DUT) using a functional interface; send, to the DUT using the functional interface, a test image for the ATE test, the test image including instructions for the DUT to enter a paused state subsequent to executing the test image; obtain results for the ATE test based at least on a determination that the DUT entered the paused state; and cause, based at least on the results, a removal of the DUT from a test fixture associated with the ATE device.
B. The at least one processor as recited in paragraph A, further comprising processing circuitry to: perform a first handshake with the DUT to cause a test interface of the DUT to execute the test image; determine that the DUT performed a second handshake indicating that the DUT entered the paused state; send, to the ATE device, the results for the ATE test; and receive, from the ATE device, data indicating whether the DUT passed or failed the ATE test, wherein the removal of the DUT from the test fixture is based at least on the data.
C. The at least one processor as recited in any one of paragraphs A-B, wherein the at least one processor is comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; or a system implemented at least partially using cloud computing resources.
D. A method comprising: storing, in a memory that is accessible to a device under test (DUT) via a functional interface, a test image for a first Automatic Test Equipment (ATE) test that is to be applied to the DUT; causing, using a first handshake, the DUT to obtain the test image from the memory using the functional interface; obtaining results for the first ATE test based at least on a second handshake; and at least one of: causing a removal of the DUT from a test fixture associated with an ATE device based at least on the results indicating the DUT failed the first ATE test; or causing a second ATE test to be applied to the DUT based at least on the results indicating the DUT passed the first ATE test.
E. The method as recited in paragraph D, wherein the first handshake causes a test interface of the DUT to change states from a paused state to an operational state, and the second handshake indicates that the test interface of the DUT has changed states from the operational state to the paused state.
F. The method as recited in any one of paragraphs D-E, further comprising: storing, in the memory, instructions for performing the second handshake, the instructions indicating at least a signature to be written at a location in the memory by the DUT to perform the second handshake, wherein the second handshake is performed by the DUT based at least on the instructions.
G. The method as recited in any one of paragraphs D-F, wherein the storing of the instructions for performing the second handshake comprises storing the instructions within the test image stored in the memory.
H. The method as recited in any one of paragraphs D-G, further comprising: storing, within the test image in the memory, an indication that a test interface of the DUT is to enter a paused state subsequent to completion of the ATE test, wherein the second handshake is indicative that the test interface changed states from an active state to the paused state.
I. The method as recited in any one of paragraphs D-H, further comprising determining that the DUT performed the second handshake based at least on a determination that a signature is stored at a location in the memory.
J. The method as recited in any one of paragraphs D-I, further comprising performing the first handshake with the DUT, wherein performing the first handshake comprises writing a signature to a register space associated with the functional interface of the DUT.
K. The method as recited in any one of paragraphs D-J, further comprising: receiving, at a computing device and from the ATE device, an indication of the first ATE test to be applied to the DUT; and based at least on the obtaining of the results for the first ATE test, sending the results for the first ATE test from the computing device to the ATE device.
L. A system comprising: one or more processors to: obtain, using a functional interface, a series of data packets including test data for an Automatic Test Equipment (ATE) test applied to a device under test (DUT); determine, based at least on a header of a data packet of the series of data packets, a portion of the DUT to apply the test data to; update the test data from a packetized format to a raw data format, the raw data format corresponding to a format of input data received using an input pin of the DUT; and apply the test data in the raw data format to the portion of the DUT to execute the ATE test.
M. The system as recited in paragraph L, wherein the one or more processors are further to: receive an indication that the test data is to be repeatedly applied to the DUT for a number of cycles; and store, in a memory of the DUT, a repeating bitstream of the test data for the number of cycles.
N. The system as recited in any one of paragraphs L-M, wherein the one or more processors are further to: receive an indication that the test data is to be repeatedly applied to the DUT for an undefined number of cycles; repeatedly apply the test data in the raw data format to the portion of the DUT; send, via the functional interface to a computing device associated with an ATE system, an indication that the test data is being applied to the DUT; and monitor the functional interface for a signal to stop applying the test data.
O. The system as recited in any one of paragraphs L-N, wherein the one or more processors are further to: determine that a second packet of the series of packets is marked as a loop end point; based at least on the second packet being marked as the loop end point, enter a loop to continuously reapply the test data from the series of packets in the raw data format to the portion of the DUT; receive an indication to stop applying the test data; and based at least on the indication, exit the loop subsequent to applying the test data of the second packet.
P. The system as recited in any one of paragraphs L-O, wherein the one or more processors are further to: determine, based at least on the header of the data packet, a cycle number to pause application of the test data; pause the application of the test data at the cycle number; and send an indication to a computing device associated with an ATE system that the application of the test data is paused.
Q. The system as recited in any one of paragraphs L-P, wherein the one or more processors are further to pulse an output pin of the DUT during execution of the ATE test, the pulse of the output pin indicative of a status of the ATE test.
R. The system as recited in any one of paragraphs L-Q, wherein the one or more processors are further to: obtain the series of data packets based at least on determination that a computing device performed a first handshake; store, using the functional interface, results of the ATE test in a memory of the computing device that is accessible to the DUT via the functional interface; and perform a second handshake with the computing device, the second handshake indicating that the DUT finished executing the ATE test.
S. The system as recited in any one of paragraphs L-R, wherein the second handshake is further indicative that a test interface of the DUT entered a pause state subsequent to finishing execution of the ATE test.
T. The system as recited in any one of paragraphs L-S, wherein the system is comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; or a system implemented at least partially using cloud computing resources.

What is claimed is:

1. At least one processor comprising:
processing circuitry to:
receive, from an Automatic Test Equipment (ATE) device, an indication of an ATE test to be applied to a device under test (DUT) using a functional interface;
send, to the DUT using the functional interface, a test image for the ATE test, the test image including instructions for the DUT to enter a paused state subsequent to executing the test image;
obtain results for the ATE test based at least on a determination that the DUT entered the paused state; and
cause, based at least on the results, a removal of the DUT from a test fixture associated with the ATE device.

2. The at least one processor of claim 1, the processing circuitry further to:
perform a first handshake with the DUT to cause a test interface of the DUT to execute the test image;
determine that the DUT performed a second handshake indicating that the DUT entered the paused state;
send, to the ATE device, the results for the ATE test; and
receive, from the ATE device, data indicating whether the DUT passed or failed the ATE test,
wherein the removal of the DUT from the test fixture is based at least on the data.

3. The at least one processor of claim 1, wherein the at least one processor is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using a large language model;
a system for performing operations using one or more vision language models (VLMs);
a system for performing operations using one or more multi-modal language models;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center; or
a system implemented at least partially using cloud computing resources.

4. A method comprising:
storing, in a memory that is accessible to a device under test (DUT) via a functional interface, a test image for a first Automatic Test Equipment (ATE) test that is to be applied to the DUT;
causing, using a first handshake, the DUT to obtain the test image from the memory using the functional interface;
obtaining results for the first ATE test based at least on a second handshake; and
at least one of:
causing a removal of the DUT from a test fixture associated with an ATE device based at least on the results indicating the DUT failed the first ATE test; or
causing a second ATE test to be applied to the DUT based at least on the results indicating the DUT passed the first ATE test.

5. The method of claim 4, wherein:
the first handshake causes a test interface of the DUT to change states from a paused state to an operational state, and
the second handshake indicates that the test interface of the DUT has changed states from the operational state to the paused state.

6. The method of claim 4, further comprising:
storing, in the memory, instructions for performing the second handshake, the instructions indicating at least a signature to be written at a location in the memory by the DUT to perform the second handshake,
wherein the second handshake is performed by the DUT based at least on the instructions.

7. The method of claim 6, wherein the storing of the instructions for performing the second handshake comprises storing the instructions within the test image stored in the memory.

8. The method of claim 4, further comprising:
storing, within the test image in the memory, an indication that a test interface of the DUT is to enter a paused state subsequent to completion of the ATE test,
wherein the second handshake is indicative that the test interface changed states from an active state to the paused state.

9. The method of claim 4, further comprising determining that the DUT performed the second handshake based at least on a determination that a signature is stored at a location in the memory.

10. The method of claim 4, further comprising performing the first handshake with the DUT, wherein performing the first handshake comprises writing a signature to a register space associated with the functional interface of the DUT.

11. The method of claim 4, further comprising:
receiving, at a computing device and from the ATE device, an indication of the first ATE test to be applied to the DUT; and
based at least on the obtaining of the results for the first ATE test, sending the results for the first ATE test from the computing device to the ATE device.

12. A system comprising:
one or more processors to:
obtain, using a functional interface, a series of data packets including test data for an Automatic Test Equipment (ATE) test applied to a device under test (DUT);
determine, based at least on a header of a data packet of the series of data packets, a portion of the DUT to apply the test data to;
update the test data from a packetized format to a raw data format, the raw data format corresponding to a format of input data received using an input pin of the DUT; and
apply the test data in the raw data format to the portion of the DUT to execute the ATE test.

13. The system of claim 12, the one or more processors further to:
receive an indication that the test data is to be repeatedly applied to the DUT for a number of cycles; and
store, in a memory of the DUT, a repeating bitstream of the test data for the number of cycles.

14. The system of claim 12, the one or more processors further to:
receive an indication that the test data is to be repeatedly applied to the DUT for an undefined number of cycles;
repeatedly applying the test data in the raw data format to the portion of the DUT;
sending, via the functional interface to a computing device associated with an ATE system, an indication that the test data is being applied to the DUT; and
monitoring the functional interface for a signal to stop applying the test data.

15. The system of claim 12, the one or more processors further to:
determine that a second packet of the series of packets is marked as a loop end point;
based at least on the second packet being marked as the loop end point, entering a loop to continuously reapply the test data from the series of packets in the raw data format to the portion of the DUT;
receiving an indication to stop applying the test data; and
based at least on the indication, exiting the loop subsequent to applying the test data of the second packet.

16. The system of claim 12, the one or more processors further to:
determine, based at least on the header of the data packet, a cycle number to pause application of the test data;
pausing the application of the test data at the cycle number; and
send an indication to a computing device associated with an ATE system that the application of the test data is paused.

17. The system of claim 12, the one or more processors further to pulse an output pin of the DUT during execution of the ATE test, the pulse of the output pin indicative of a status of the ATE test.

18. The system of claim 12, the one or more processors further to:
obtain the series of data packets based at least on determination that a computing device performed a first handshake;
store, using the functional interface, results of the ATE test in a memory of the computing device that is accessible to the DUT via the functional interface; and
perform a second handshake with the computing device, the second handshake indicating that the DUT finished executing the ATE test.

19. The system of claim 18, wherein the second handshake is further indicative that a test interface of the DUT entered a pause state subsequent to fishing execution of the ATE test.

20. The system of claim 12, wherein the system is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using a large language model;
a system for performing operations using one or more vision language models (VLMs);
a system for performing operations using one or more multi-modal language models;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center; or
a system implemented at least partially using cloud computing resources.
